(19) United States
(12) Patent Application Publication
(10) Pub. No.: US 2025/0261366 A1
(43) Pub. Date: Aug. 14, 2025

(54) Memory Circuitry And Methods Used In Forming Memory Circuitry

(71) Applicant: Micron Technology, Inc., Boise, ID (US)

(72) Inventors: Sok Han Wong, Boise, ID (US); Adharsh Rajagopal, Meridian, ID (US); John F. Kaeding, Boise, ID (US); Peng Cheng, Meridian, ID (US); David Daycock, Boise, ID (US); Eyob N. Tarekegn, Meridian, ID (US)

(73) Assignee: Micron Technology, Inc., Boise, ID (US)

(21) Appl. No.: 19/042,179

(22) Filed: Jan. 31, 2025

Related U.S. Application Data
(60) Provisional application No. 63/552,795, filed on Feb. 13, 2024.

(51) Int. Cl. H10B 12/00

(52) U.S. Cl. CPC H10B 12/50; H10B 12/0387; H10B 12/09; H10B 12/482

(57) ABSTRACT

Memory circuitry comprises vertically-alternating tiers of insulative material and memory cells. The memory cells individually comprise a capacitor and a horizontally-oriented transistor. Semiconductor material is directly below the vertically-alternating tiers. Insulative vertical walls extend through the vertically-alternating tiers into the semiconductor material there-below. Individual of the insulative vertical walls below a top of the semiconductor material comprise an upper portion directly above and joined with a lower portion. The individual insulative vertical walls comprise at least one external jog surface in a vertical cross-section in and below the top of the semiconductor material where the upper and lower portions join. The lower portion is wider in the vertical cross-section in the semiconductor material than the upper portion where the upper and lower portions join in the semiconductor material. Method embodiments are disclosed.

### TECHNICAL FIELD

Embodiments disclosed herein pertain to memory circuitry and to methods used in forming memory circuitry.

### BACKGROUND

Memory is one type of integrated circuitry and is used in computer systems for storing data. Memory may be fabricated in one or more arrays of individual memory cells. Memory cells may be written to, or read from, using digitlines (which may also be referred to as bitlines, data lines, or sense lines) and access lines (which may also be referred to as wordlines). The sense lines may conductively interconnect memory cells along columns of the array, and the access lines may conductively interconnect memory cells along rows of the array. Each memory cell may be uniquely addressed through the combination of a sense line and an access line.

Memory cells may be volatile, semi-volatile, or non-volatile. Non-volatile memory cells can store data for extended periods of time in the absence of power. Non-volatile memory is conventionally specified to be memory having a retention time of at least about 10 years. Volatile memory dissipates and is therefore refreshed/rewritten to maintain data storage. Volatile memory may have a retention time of milliseconds or less. Regardless, memory cells are configured to retain or store memory in at least two different selectable states. In a binary system, the states are considered as either a “0” or a “1”. In other systems, at least some individual memory cells may be configured to store more than two levels or states of information.

Memory cells may be arranged or arrayed in several manners including, for example, in a vertical stack (e.g., along a z direction) comprising a three-dimensional (3D) memory array region having horizontal tiers in which individual memory cells are received (e.g., arrayed in x and y directions). The stack in the 3D memory array region comprises vertically-alternating insulative tiers and conductive tiers that extend into a stair-step region. The stair-step region includes individual “stairs” (alternately termed “steps” or “stair-steps”) that define contact regions of conductive lines of individual of the conductive tiers to which vertical conductive vias can contact to provide electrical access to/from those conductive lines.

### BRIEF DESCRIPTION OF THE DRAWINGS

FIG. 1 is a diagrammatic schematic of a DRAM memory array and peripheral circuitry in accordance with the prior art and in accordance with an embodiment of the invention.

FIG. 2 is an enlargement of a portion of FIG. 1.

FIGS. 3-5 are diagrammatic cross-sectional views of portions of a construction that will comprise circuitry in accordance with an embodiment of the invention.

FIGS. 6-19 are diagrammatic sequential sectional and/or enlarged views of the construction of FIGS. 3-5, or portions thereof or alternate and/or additional embodiments, in process in accordance with some embodiments of the invention.

### DETAILED DESCRIPTION OF EXAMPLE EMBODIMENTS

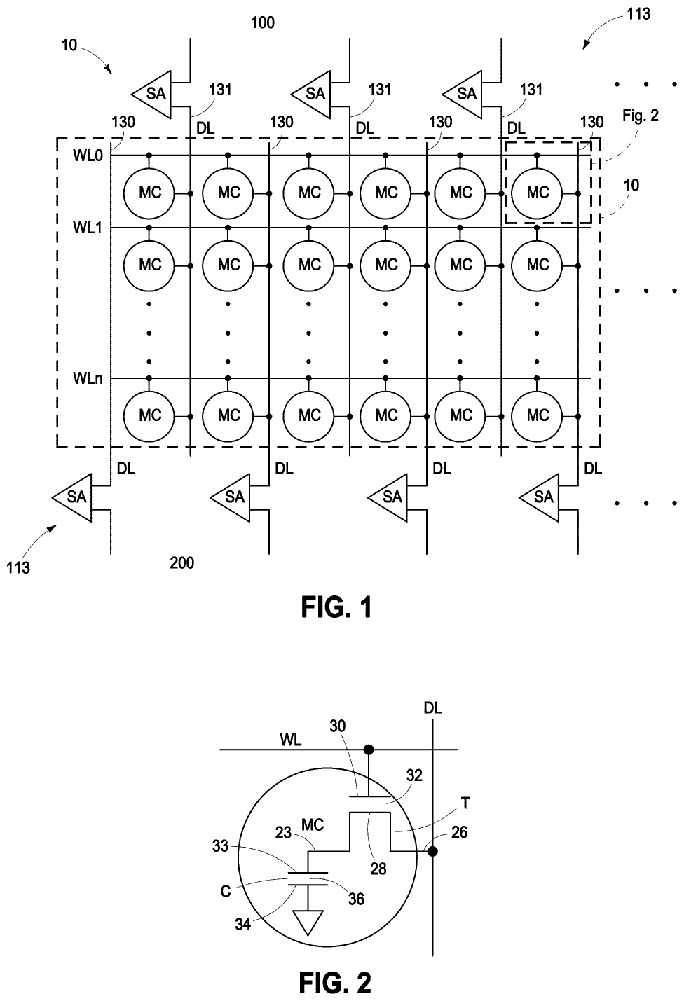

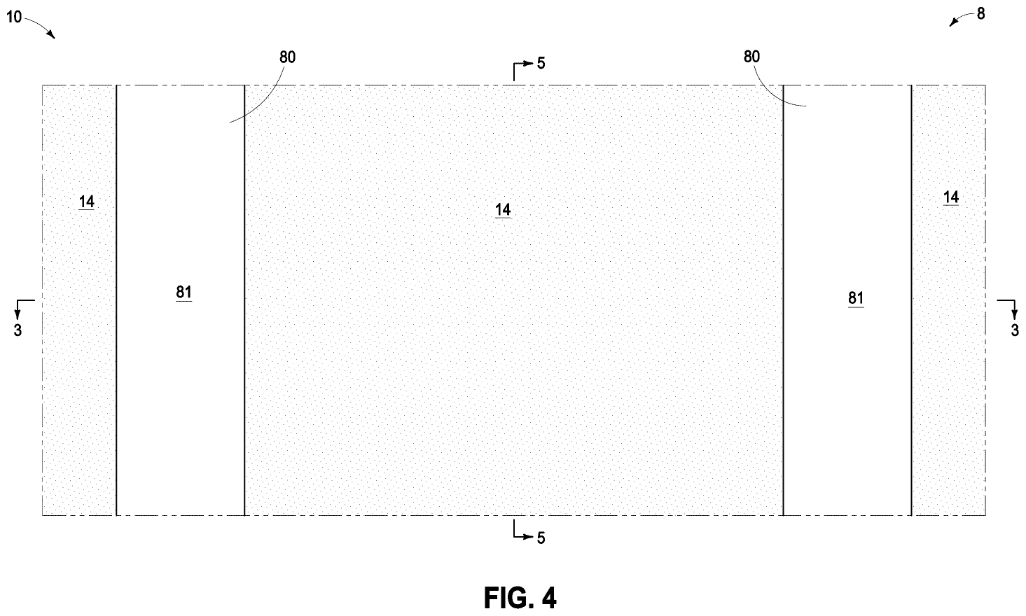

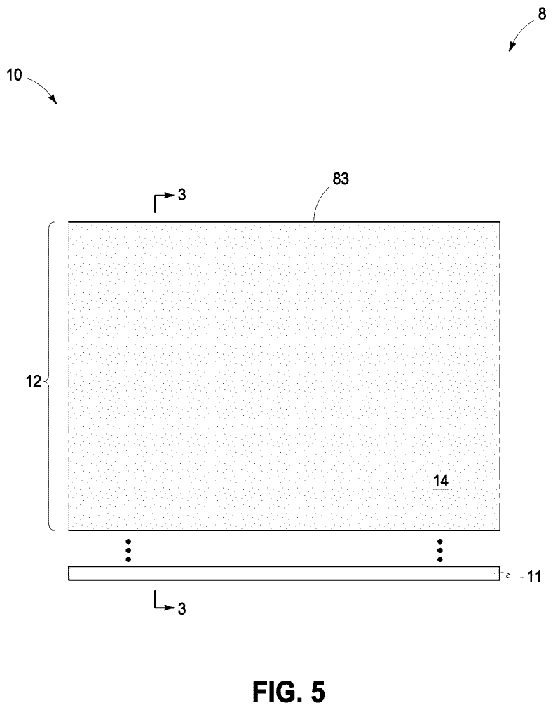

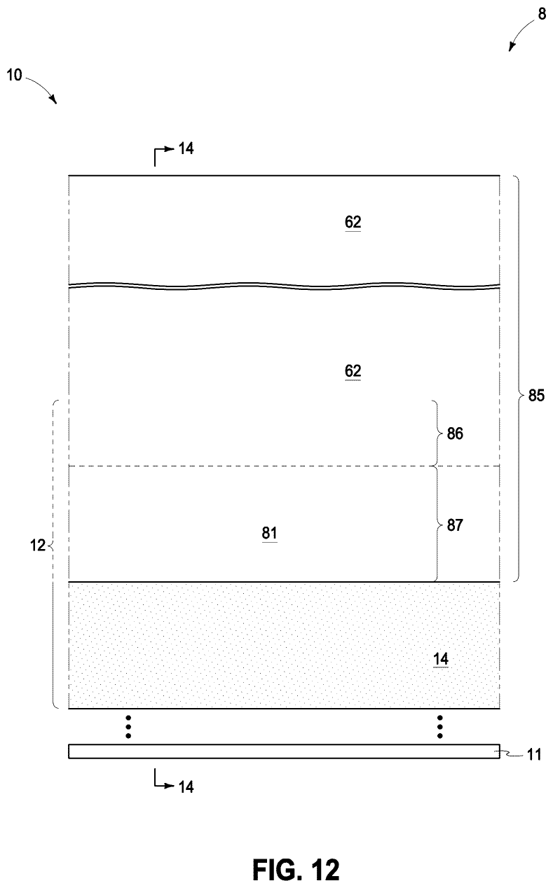

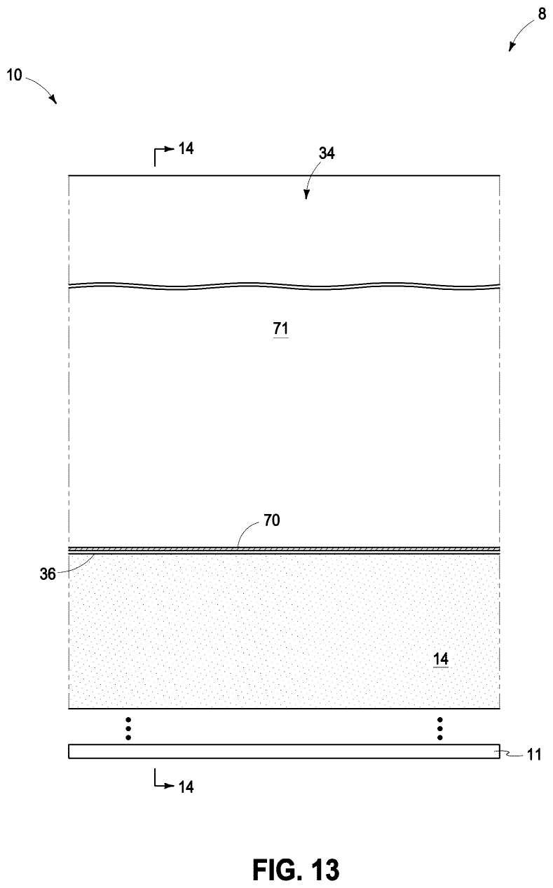

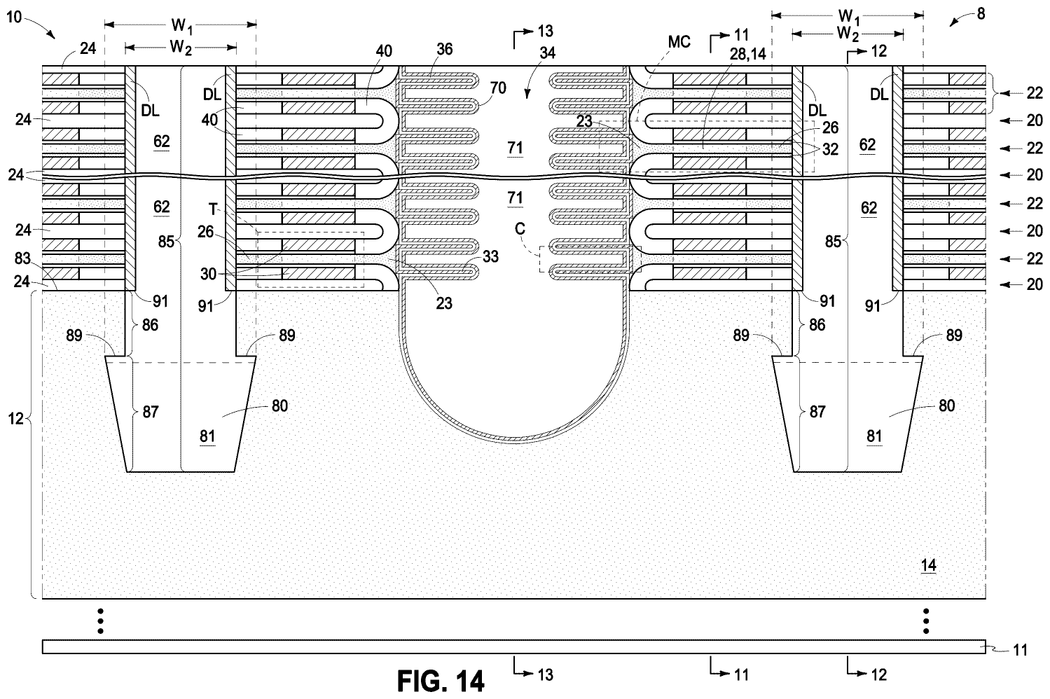

Embodiments of the invention encompass memory circuitry (e.g., DRAM) having vertically-alternating tiers of insulative material and memory cells, with the memory cells individually comprising a capacitor and a horizontally-oriented transistor. Embodiments of the invention also encompass methods used in forming such memory circuitry. Example method embodiments are first described with reference to FIGS. 1-19.

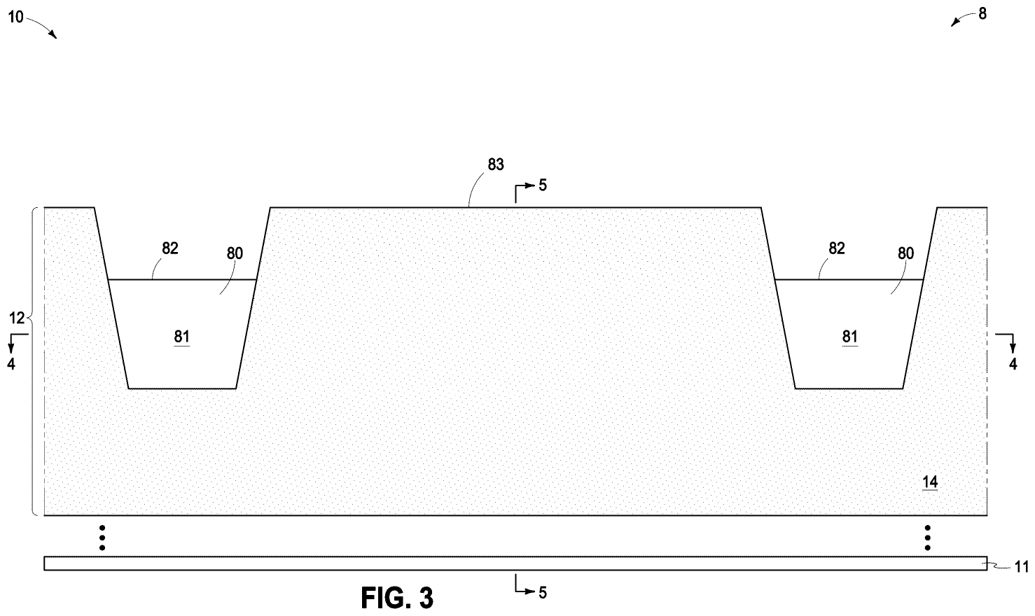

One example prior art schematic diagram of DRAM circuitry, and in accordance with an embodiment of the invention, is shown in FIGS. 1 and 2. FIG. 2 shows example memory cells MC individually comprising a transistor T and a capacitor C. One electrode of capacitor C is directly electrically coupled to a suitable potential (e.g., ground) and the other capacitor electrode is contacted with or comprises one of the source/drain regions of transistor T. The other source/drain region of transistor T is directly electrically coupled with a digitline/sense line 130 or 131 (also individually designated as DL). The gate of transistor T is directly electrically coupled with (e.g., comprises part of) a wordline/access line WL. FIG. 1 shows digitlines 130 and 131 extending from one of opposite sides 100 and 200 of a memory array area 10 into a peripheral circuitry area 113 that is aside memory array area 10. Digitlines 130 and 131 individually directly electrically couple with a sense amp SA on opposite sides 100 and 200 of array area 10 within peripheral circuitry area 113. Non-schematic structure embodiments as shown herein in FIGS. 3+ have the wordlines/access lines running horizontally and the digitlines/sense lines running vertically. This could be reversed or other orientations used. Further, and by way of example only, sense amps SA could be on only one side or all directly above or directly below memory array area 10.

Referring to FIGS. 3-5, an example fragment of a substrate construction 8 comprising array or array area 10 has been fabricated relative to a base substrate 11. Substrate 11 may comprise any one or more of conductive/conductor/conducting, semiconductive/semiconductor/semiconducting, and insulative/insulator/insulating (i.e., electrically herein) materials. Materials may be aside, elevationally inward, or elevationally outward of the FIGS. 3-5-depicted materials. For example, other partially or wholly fabricated components of integrated circuitry may be provided somewhere above, about, or within base substrate 11. Control and/or other peripheral circuitry for operating components within a memory array may also be fabricated and may or may not be wholly or partially within a memory array or sub-array. Further, multiple sub-arrays may also be fabricated and operated independently, in tandem, or otherwise relative one another. As used in this document, a “sub-array” may also be considered as an array.

Semiconductor material 12 is above base substrate 11. In one embodiment, semiconductor material 12 comprises silicon material 14 (e.g., elemental monocrystalline or polycrystalline silicon and which may include one or more additional elements). If, by way of example, base substrate 11 is bulk monocrystalline silicon, silicon material 14 may be an upper or uppermost portion of such bulk monocrystalline silicon.

Parallel and spaced lower walls 80 have been formed in semiconductor material 12. Lower walls 80 may be considered as being a series of etch-stop walls 80. Walls 80 may taper laterally inward moving deeper into semiconductor material 12 (as shown). Individual lower walls 80 comprise wall material 81 and have a top 82 that is spaced below a top 83 of semiconductor material 12. In one embodiment, wall material 81 is insulating (e.g., comprising silicon dioxide and/or silicon nitride), and in one embodiment at least some of which remains in a finished-circuitry construction. An example manner of forming walls 80 comprises etching corresponding trenches into semiconductor material 12, overfilling such with material 81, planarizing material 81 back at least to semiconductor material 12, and followed by wet-etching such back to produce the construction as shown.

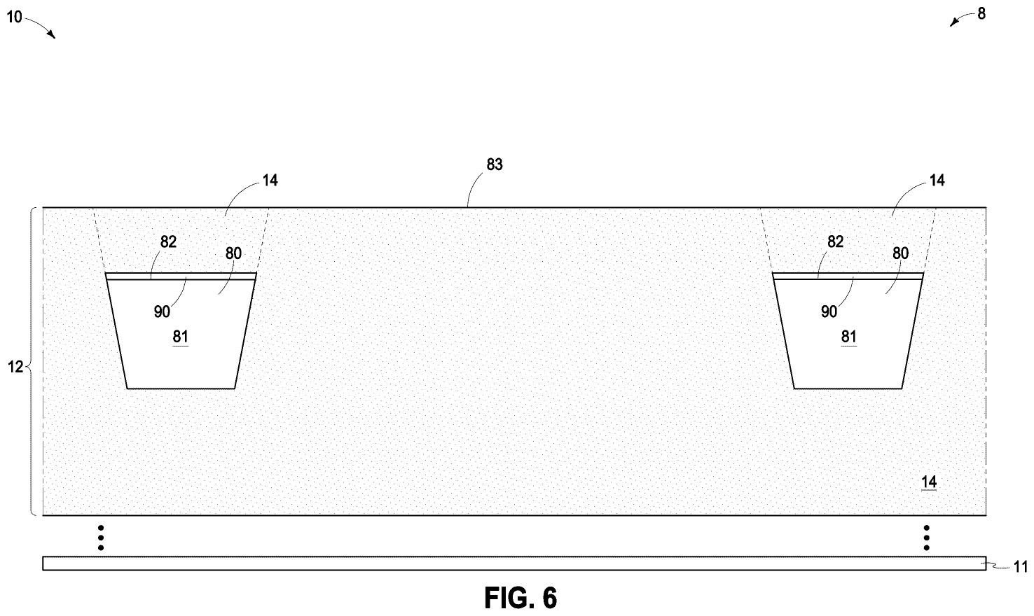

Referring to FIG. 6, semiconductive material has been epitaxially formed from semiconductor material 12 to cover over individual lower walls 80. In one embodiment and as shown, such epitaxially-formed semiconductive material comprises silicon material 14. Additional or alternate semiconductor materials may be epitaxially formed (not shown; e.g., silicon-germanium material 13 as described below). In one embodiment and as shown, the covering-semiconductive material forms a void space 90 between top 82 of individual lower walls 80 and the epitaxially-formed semiconductive material (e.g., silicon material 14). Example void space 90 is shown as being rectangular in vertical cross-section, although the top thereof may be curved, have multiple straight and/or curved segments, a combination of curved and straight segments, etc. An example manner of epitaxially forming silicon material 14 includes using SiH₄, Si₂H₆, H₂SiCl₂, HCl, and Cl₂ as precursors at 300° C. to 1,500° C. and 100 mTorr to 100 Torr. The covering-semiconductive material (e.g., silicon material 14) will also form atop semiconductor material 12 (effectively thickening semiconductor material 12 at least initially, and not shown) and such may be planarized back at least some (e.g., back to original top 83 as shown, including less or more removing thereof [neither being shown]).

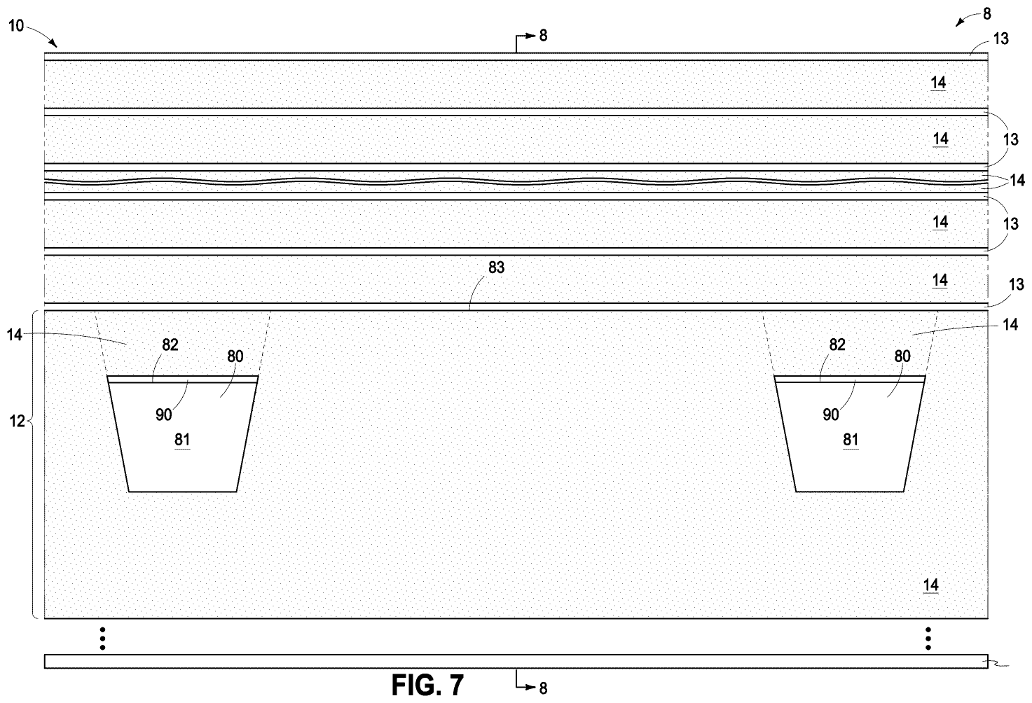

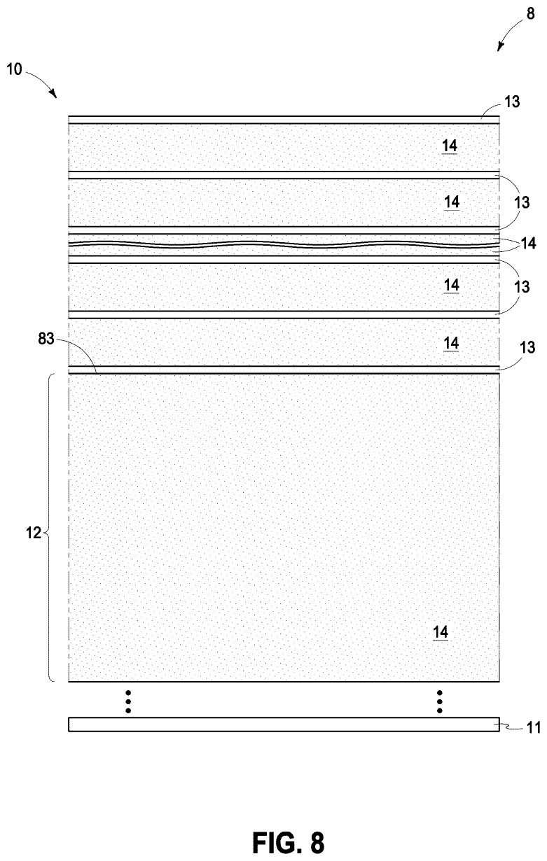

Referring to FIGS. 7 and 8, vertically-alternating layers comprising silicon material 14 and silicon-germanium material 13 have been epitaxially formed directly above semiconductor material 12 and semiconductive-material-covered lower walls 80 (e.g., using GeH₄ as the germanium source in addition to the above precursors when epitaxially forming silicon-germanium material 13). Example silicon-germanium material 13 is Si₁₋ₓGeₓ, and which may include one or more additional elements. Materials 14 and 13 are ideally of etchably-different compositions relative one another.

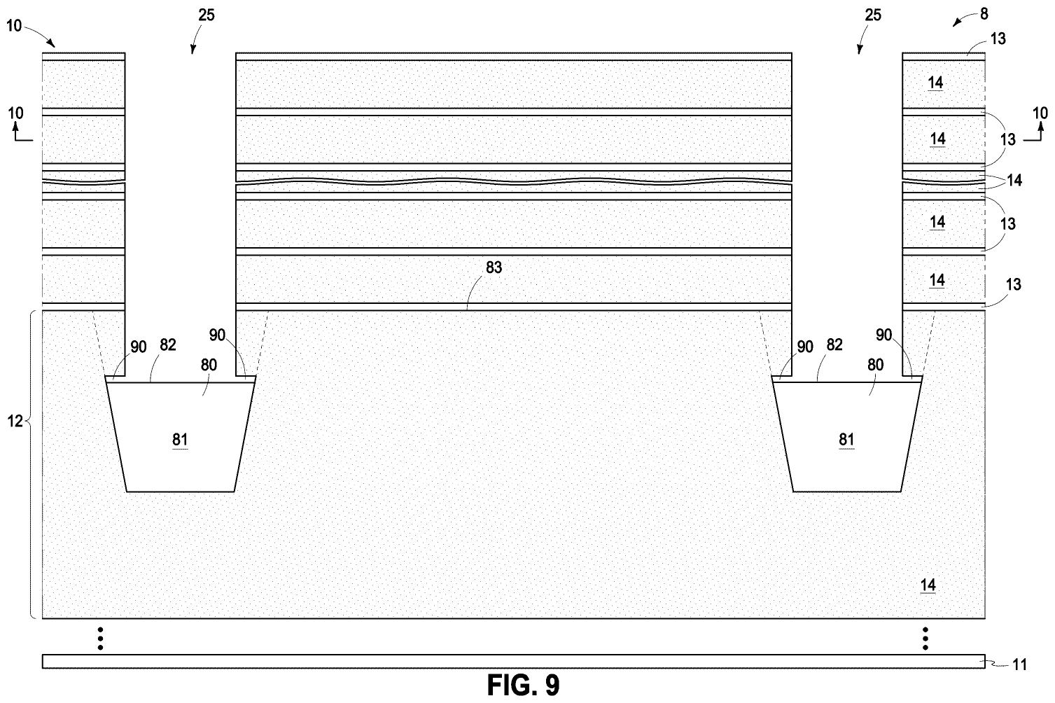

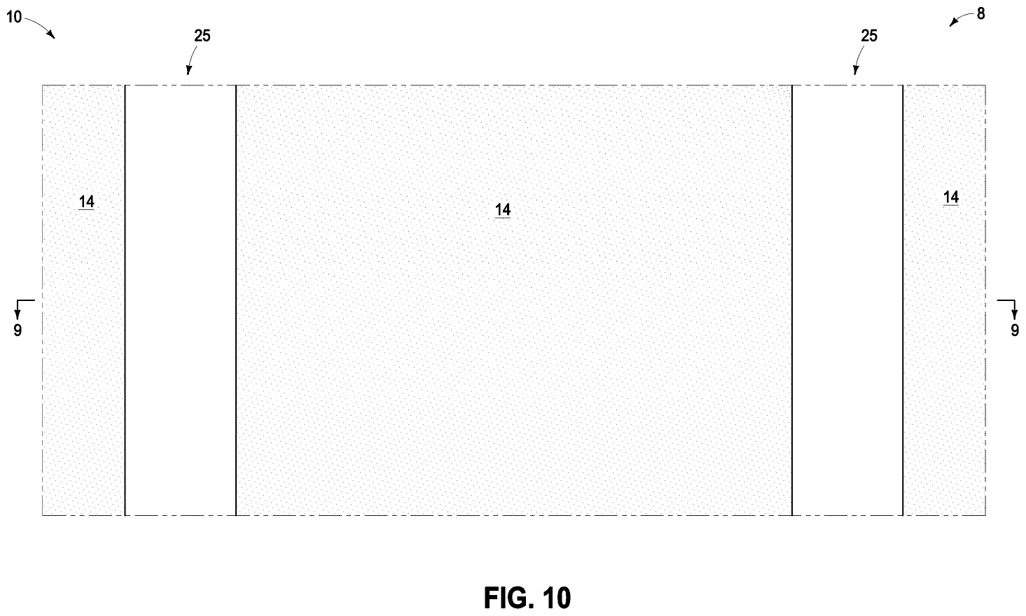

Referring to FIGS. 9 and 10, parallel and spaced trenches 25 have been etched through the vertically-alternating layers (and the epitaxially-formed semiconductive material when present), with trenches 25 individually being directly above and longitudinally along one of individual walls 80. Trenches 25 are so etched through individual void spaces 90 (when present) and to individual walls 80 using wall material 81 of individual walls 80 as an etch stop during such etching. Etching may occur into walls 80/wall material 81 (not shown). Trenches 25 may be formed, for example, using openings in photoresist and/or hard-masking material during such etching. Etching chemistry would likely be changed during such etching depending on whether etching through silicon material 14 or silicon-germanium material 13, with such last-etching thereof stopping atop or within wall material 81 of walls 80. Trenches 25 may taper laterally inward moving deeper into the construction (not shown). Ideally, a bottom (at least) of individual trenches 25 is narrower than the top of the individual lower wall 80 to which such individual trench 25 is etched (e.g., to hopefully avoid over-etch laterally of lower walls 80 into silicon material 14).

Referring to FIGS. 2 and 11-14, and after etching trenches 25, silicon-germanium material 13 has been removed (no longer shown; e.g., by etching) selectively relative to silicon material 14, and in one embodiment with such silicon material 14 during such removing or subsequently being at least partially thinned, for example in manners not material to the inventions disclosed herein (as shown; e.g., as shown in Micron Technology's U.S. Patent Application Publication Nos. 2022/0254784, 2022/0130834, U.S. Pat. No. 11,342,218, etc.). Vertically-alternating tiers 20 and 22 of insulative material 24 (e.g., silicon dioxide) and memory cells MC, respectively, have then been formed.

Memory cells MC individually comprise a capacitor C and a horizontally-orientated transistor T having a channel/channel material 28 comprising epitaxially-formed silicon material 14. Example transistor T comprises source/drain regions 23 and 26 (indicated with heavier stippling than channel material 28) having channel material 28 laterally there-between. Regions 23, 26, and 28 of different immediately-horizontally-adjacent memory cells MC into and out of the plane of the page upon which FIG. 14 lies in a common memory-cell tier 22 may be isolated relative one another by insulative material (not shown). Transistor T also comprises a gate 30 (e.g., gate-all-around the channel; e.g., conductive metal material) having a gate insulator 32 (e.g., dielectric or ferroelectric) between at least channel material 28 and gate 30. An example insulator 40 (e.g., silicon nitride) is laterally against lateral sides/edges of gates 30. Source/drain regions 23 and 26 are individually shown as having a lateral edge that is laterally-coincident with a lateral edge of gate 30, although there may be a dopant-concentration gradient between channel material 28 and a highest-dopant concentration within source/drain regions 23 and/or 26. Additionally and/or alternately, source/drain regions 23 and/or 26 may include an LDD region, a halo region, etc. (neither being shown). Example capacitor C comprises a storage-node electrode 33, a common cell plate 34 (e.g., comprising conductive metal material 70 and conductively-doped polysilicon 71), and a capacitor insulator 36 there-between (e.g., dielectric or ferroelectric). Source/drain region 23 of transistor T is directly electrically coupled with and/or may be considered as a part of storage-node electrode 33. Source/drain region 26 of transistor T is directly electrically coupled with a digitline DL. Digitlines DL of different immediately-horizontally-adjacent memory cells MC into and out of the plane of the page upon which FIG. 14 lies in a common memory-cell tier 22 may be isolated relative one another by insulative material (not shown).

In one embodiment and as shown, insulator material 62 (e.g., silicon dioxide and/or silicon nitride) is formed in remaining trenches 25 directly above and directly against insulating material 81 of lower walls 80. Insulator material 62 and insulating material 81 may be of the same or different composition(s) relative one another. In one such embodiment, insulating material 81 of lower walls 80 and insulator material 62 collectively comprise insulative vertical walls 85 extending through vertically-alternating tiers 20 and 22 into semiconductor material 12. Individual insulative vertical walls 85 below top 83 of semiconductor material 12 comprise an upper portion 86 directly above and joined with a lower portion 87. Individual insulative vertical walls 85 comprise at least one external jog surface 89 (two being shown) in a vertical cross-section (e.g., the vertical cross-section that is FIG. 14) in and below top 83 of semiconductor material 12 where upper and lower portions 86 and 87 join. In this document, a “jog surface” is characterized or defined by an abrupt change in direction [at least 15°] in comparison to surfaces that are immediately-above and immediately-below the jog surface. Lower portion 87 is wider (e.g., W₁) in the vertical cross-section in semiconductor material 12 than upper portion 86 where upper and lower portions 86 and 87 join in semiconductor material 12 (e.g., W₂). In one embodiment and as shown, the at least one external jog surface 89 (e.g., both as shown) includes a part (at least a part, all as shown) that is horizontal in the vertical cross-section.

In one embodiment, and as shown, channel 28 is horizontally between two source/drain regions 23 and 26, with capacitor C being directly electrically coupled to one of the source/drain regions (e.g., 23) in individual of memory-cell tiers 22. A digit line DL has been formed to extend vertically through vertically-alternating tiers 20, 22 on each of two opposing lateral sides of individual of remaining trenches 25 in a vertical cross-section (e.g., that of FIG. 14) before forming insulator material 62 in remaining trenches 25. Vertical digit DL is directly electrically coupled to multiple of the other of the source/drain regions (e.g., 26) in different ones of individual memory-cell tiers 22. Insulator material 62 is then formed in remaining trenches 25 laterally between the two vertical digit lines DL therein.

Any other attribute(s) or aspect(s) as shown and/or described herein with respect to other embodiments may be used in the embodiments shown and described with reference to the above embodiments.

In one embodiment, a method used in forming memory circuitry (e.g., 10) comprises forming parallel and spaced lower walls (e.g., 80) in semiconductor material (e.g., 12). Individual of the lower walls comprise insulating material (e.g., 81) and having a top (e.g., 82) that is spaced below a top (e.g., 83) of the semiconductor material. Semiconductive material (e.g., 14) is epitaxially formed from the semiconductor material to cover the top of the individual lower walls (e.g., regardless of whether a void space is formed). Vertically-alternating layers comprising silicon material (e.g., 14) and silicon-germanium material (e.g., 13) are epitaxially formed directly above the semiconductor material and the semiconductive-material-covered lower walls. Parallel and spaced trenches (e.g., 25) are formed through the vertically-alternating layers. The trenches individually are directly above and longitudinally along one of the individual lower walls. The trenches are etched to the individual lower walls and using the insulating material of the individual lower walls as an etch stop during the etching of the trenches. After such etching, silicon-germanium material is removed (e.g., by etching) selectively relative to the silicon material and vertically-alternating tiers (e.g., 20, 22) of insulative material (e.g., 24) and memory cells (e.g., MC) are formed. The memory cells individually comprise a capacitor (e.g., C) and a horizontally-oriented transistor (e.g., T) having a channel (e.g., 28) comprising the epitaxially-formed silicon material. Insulator material (e.g., 62) is formed in remaining of the trenches directly above and directly against the insulating material of the lower walls. Any other attribute(s) or aspect(s) as shown and/or described herein with respect to other embodiments may be used.

Heretofore, example processing as described above in forming trenches 25 achieved depth thereof in semiconductor material 12 by a timed etch. Using wall material(s) 81 as an etch-stop may provide more precise control of depth of trenches 25 in semiconductor material 12.

Alternate embodiment constructions may result from method embodiments described above, or otherwise. Regardless, embodiments of the invention encompass circuitry independent of method of manufacture. Nevertheless, such circuitry arrays may have any of the attributes as described herein in method embodiments. Likewise, the above-described method embodiments may incorporate, form, and/or have any of the attributes described with respect to device embodiments.

In one embodiment, memory circuitry (e.g., 10) comprises vertically-alternating tiers (e.g., 20, 22) of insulative material (e.g., 24) and memory cells (e.g., MC). The memory cells individually comprise a capacitor (e.g., C) and a horizontally-oriented transistor (e.g., T). Semiconductor material (e.g., 12) is directly below the vertically-alternating tiers. Insulative vertical walls (e.g., 85) extend through the vertically-alternating tiers into the semiconductor material. Individual of the insulative vertical walls below a top (e.g., 83) of the semiconductor material comprise an upper portion (e.g., 86) directly above and joined with a lower portion (e.g., 87). The individual insulative vertical walls comprise at least one external jog surface (e.g., 89) in a vertical cross-section in and below the top of the semiconductor material where the upper and lower portions join. The lower portion is wider (e.g., W₁) in the vertical cross-section in the semiconductor material than the upper portion where the upper and lower portions join in the semiconductor material (e.g., W₂).

In one embodiment, individual digit lines DL have a bottom 91 that is not directly above any of the jog surfaces in the vertical cross-section. In one embodiment, external jog surface 89 is directly under the other source/drain region 26 of one of memory cells MC in a lowest of memory-cell tiers 22 in the vertical cross-section. In one embodiment, two external jog surfaces 89 are in individual insulative vertical walls 85 in the vertical cross-section. Each of jog surfaces 89 is directly under the other source/drain region 26 of one of memory cells MC in a lowest of memory-cell tiers 22 in the vertical cross-section.

Any other attribute(s) or aspect(s) as shown and/or described herein with respect to other embodiments may be used.

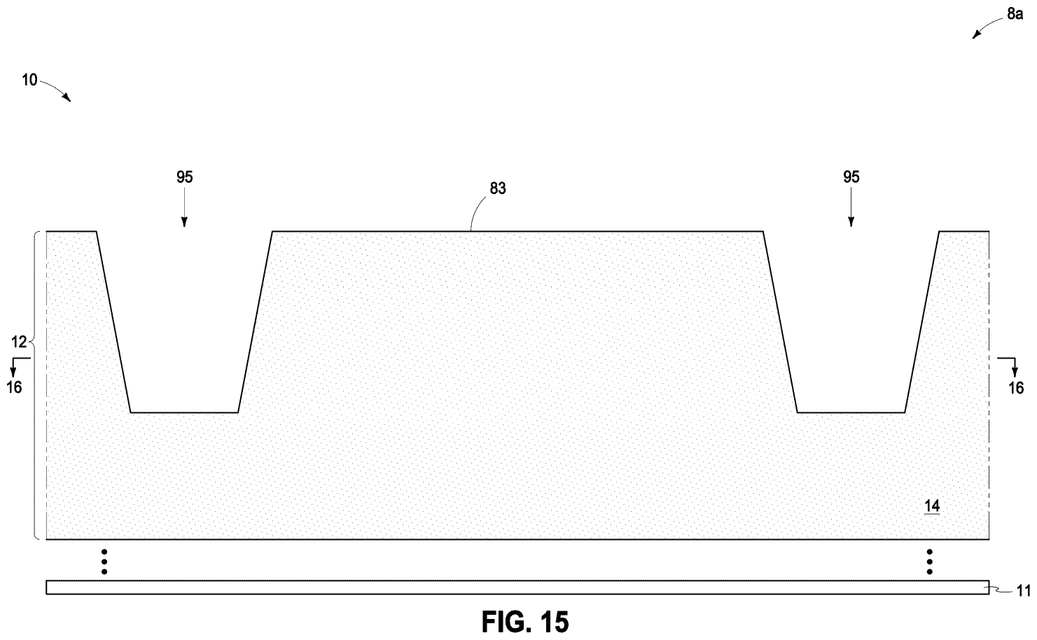

Another method embodiment used in forming memory circuitry is described with reference to FIGS. 15-19 and with respect to a construction 8a. Like numerals from the above-described embodiments have been used where appropriate, with some construction differences being indicated with the suffix “a” or with different numerals.

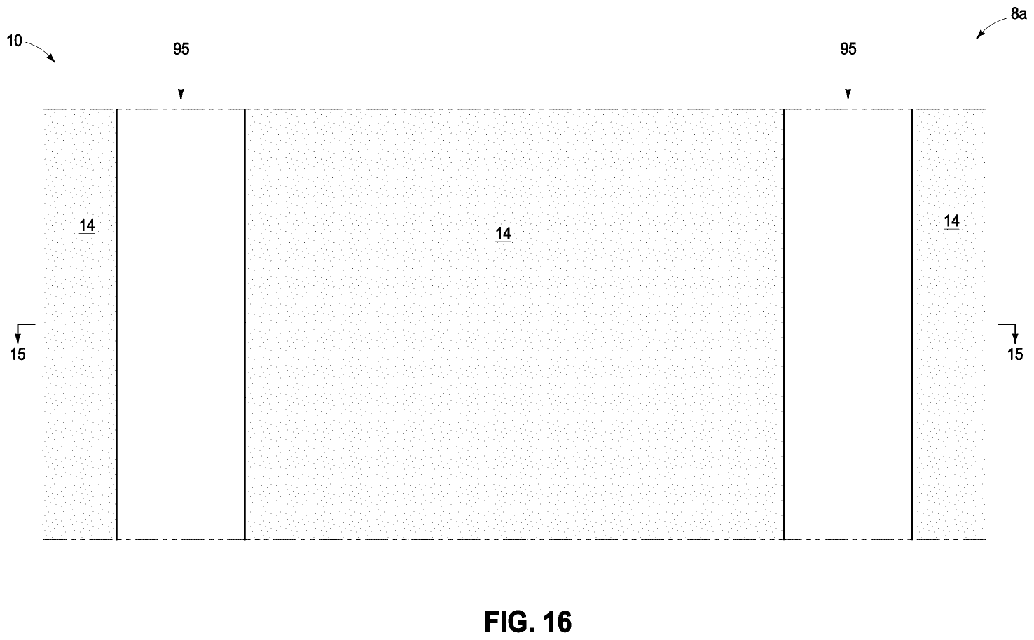

Referring to FIGS. 15 and 16, parallel and spaced first trenches 95 have been formed in semiconductor material 12.

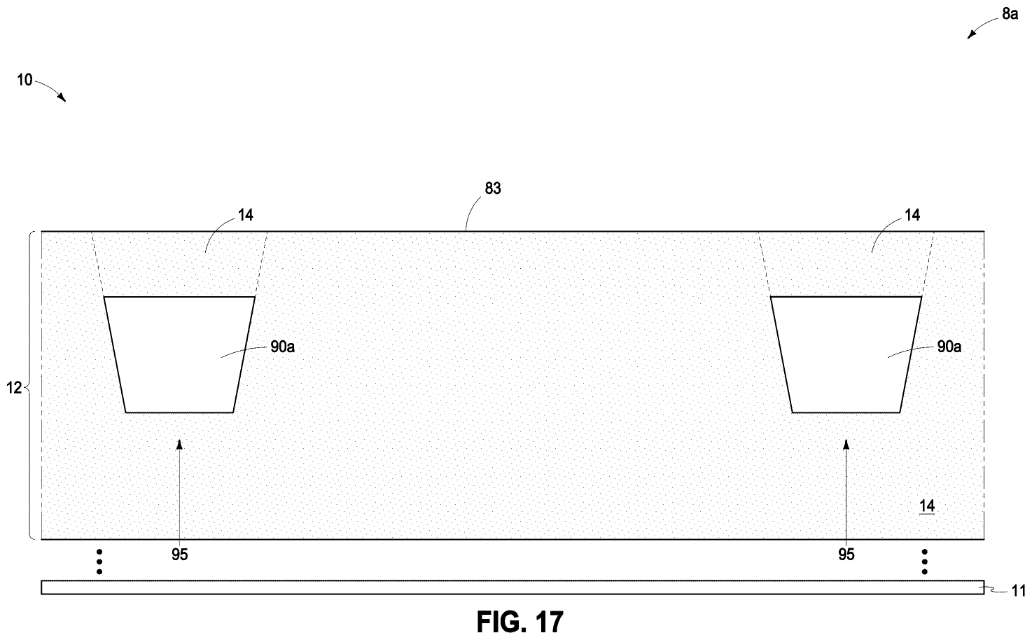

Referring to FIG. 17, semiconductive material (e.g., 14) has been formed epitaxially from semiconductor material 12 to cover over individual first trenches 95 to leave at least a portion of individual first trenches 95 directly under the epitaxially-formed semiconductor material (e.g., forming/leaving void space 90a). The semiconductive material may be planarized back at least somewhat (e.g., even back to or below original top 83 if desired).

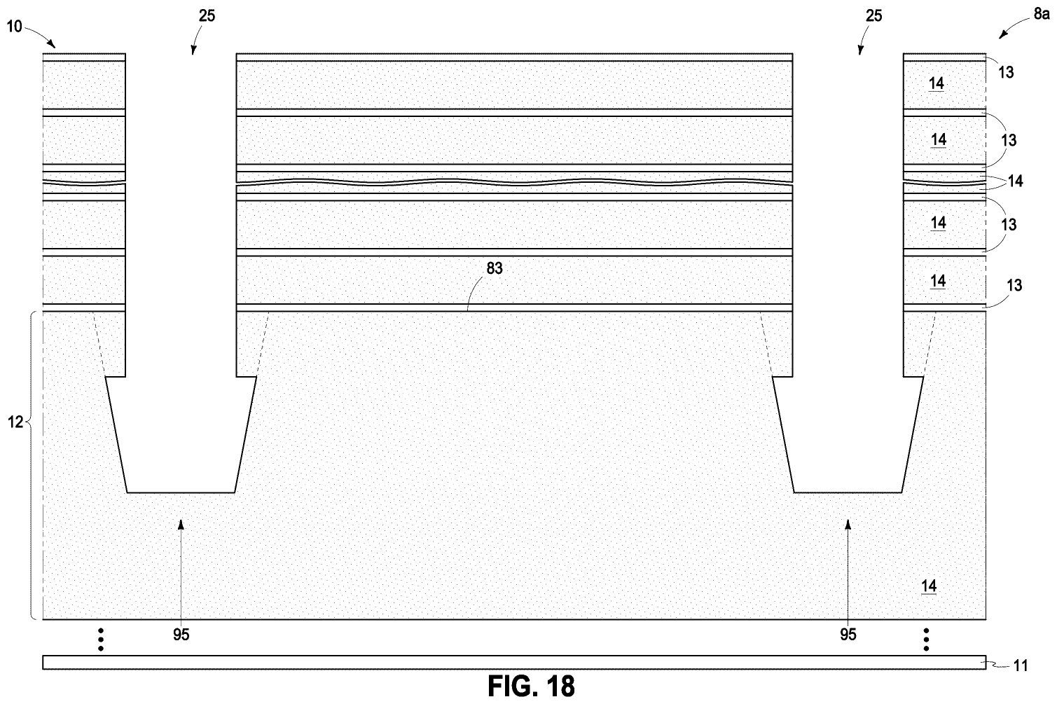

Referring to FIG. 18, vertically-alternating layers comprising silicon material 14 and silicon-germanium material 13 have been epitaxially formed directly above the semiconductor material and the semiconductive-material-covered first trenches (like in FIGS. 7 and 8). Then, parallel and spaced second trenches 25 have been etched through the vertically-alternating layers, with second trenches 25 individually being directly above and longitudinally along one of individual covered first trenches 95. Second trenches 25 are etched to first trenches 95 to interconnect first trenches 95 and second trenches 25 together (like in FIGS. 9 and 10, but in the absence of walls 80). Leaving at least a portion of individual first trenches 95 directly under the epitaxially-formed semiconductor material may provide somewhat of a buffering-etch-stop effect even in the absence of walls 80, but likely not as effective as if walls 80 are used instead.

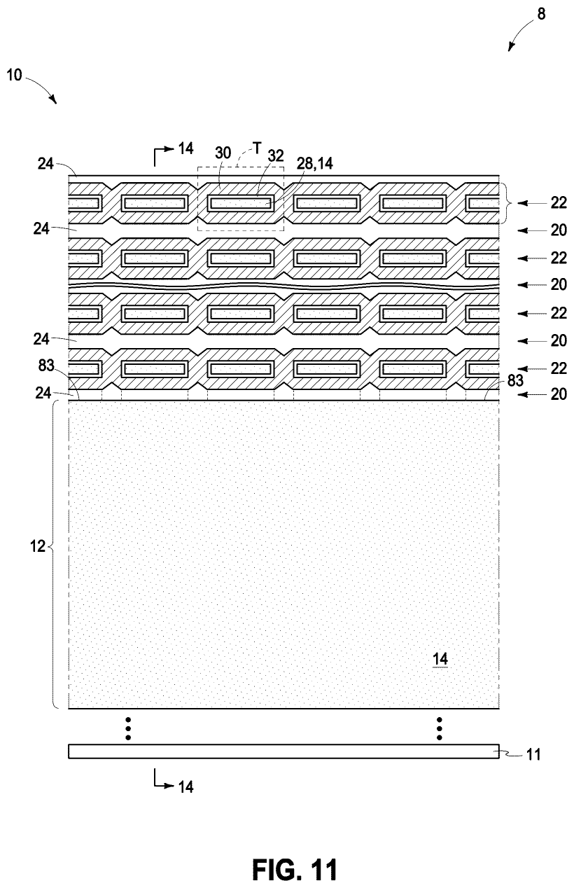

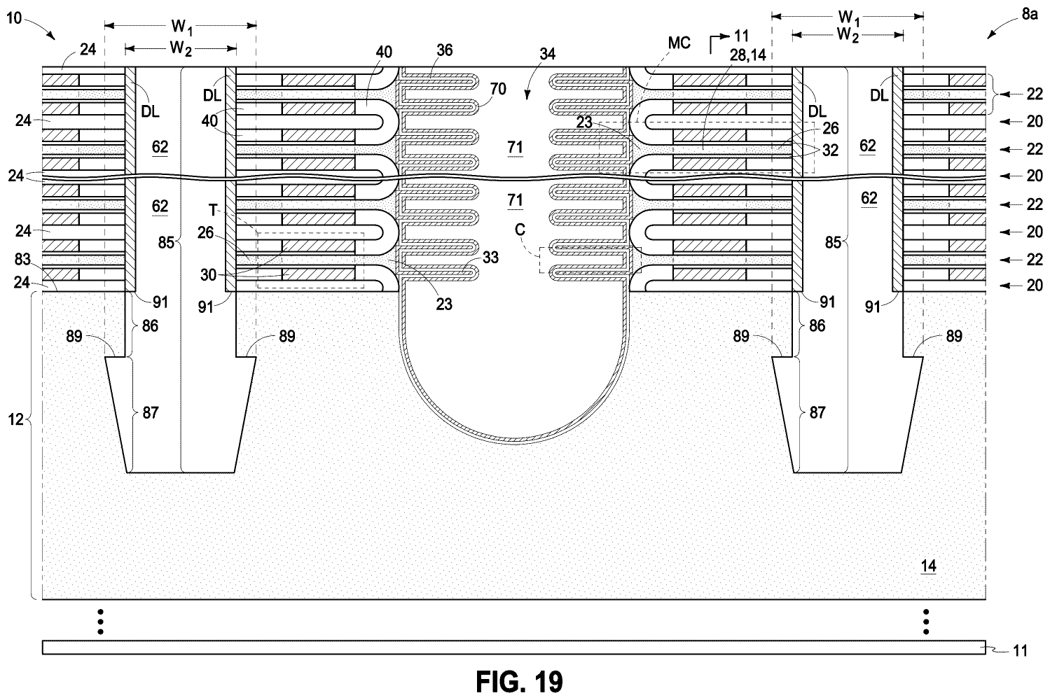

Referring to FIG. 19, and after such etching, silicon-germanium material 13 (not shown) has been removed (e.g., by etching) selectively relative to silicon material 14 and vertically-alternating tiers 20, 22 of insulative material 24 and memory cells MC have been formed (like in FIGS. 11-14). Memory cells MC individually comprise a capacitor C and a horizontally-oriented transistor T having a channel 28 comprising the epitaxially-formed silicon material 14. Any other attribute(s) or aspect(s) as shown and/or described herein with respect to other embodiments may be used.

The above processing(s) or construction(s) may be considered as being relative to an array of components formed as or within a single stack or single deck of such components above or as part of an underlying base substrate (albeit, the single stack/deck may have multiple tiers). Control and/or other peripheral circuitry for operating or accessing such components within an array may also be formed anywhere as part of the finished construction, and in some embodiments may be under the array (e.g., CMOS under-array). Regardless, one or more additional such stack(s)/deck(s) may be provided or fabricated above and/or below that shown in the figures or described above. Further, the array(s) of components may be the same or different relative one another in different stacks/decks and different stacks/decks may be of the same thickness or of different thicknesses relative one another. Intervening structure may be provided between immediately-vertically-adjacent stacks/decks (e.g., additional circuitry and/or dielectric layers). Also, different stacks/decks may be electrically coupled relative one another. The multiple stacks/decks may be fabricated separately and sequentially (e.g., one atop another), or two or more stacks/decks may be fabricated at essentially the same time.

The assemblies and structures discussed above may be used in integrated circuits/circuitry and may be incorporated into electronic systems. Such electronic systems may be used in, for example, memory modules, device drivers, power modules, communication modems, processor modules, and application-specific modules, and may include multilayer, multichip modules. The electronic systems may be any of a broad range of systems, such as, for example, cameras, wireless devices, displays, chip sets, set top boxes, games, lighting, vehicles, clocks, televisions, cell phones, personal computers, automobiles, industrial control systems, aircraft, etc.

In this document unless otherwise indicated, “elevational”, “higher”, “upper”, “lower”, “top”, “atop”, “bottom”, “above”, “below”, “under”, “beneath”, “up”, and “down” are generally with reference to the vertical direction. “Horizontal” refers to a general direction (i.e., within 10 degrees) along a primary substrate surface and may be relative to which the substrate is processed during fabrication, and vertical is a direction generally orthogonal thereto. Reference to “exactly horizontal” is the direction along the primary substrate surface (i.e., no degrees there-from) and may be relative to which the substrate is processed during fabrication. Further, “vertical” and “horizontal” as used herein are generally perpendicular directions relative one another and independent of orientation of the substrate in three-dimensional space. Additionally, “elevationally-extending” and “extend(ing) elevationally” refer to a direction that is angled away by at least 45° from exactly horizontal. Further, “extend(ing) elevationally”, “elevationally-extending”, “extend(ing) horizontally”, “horizontally-extending” and the like with respect to a field effect transistor are with reference to orientation of the transistor's channel length along which current flows in operation between the source/drain regions. For bipolar junction transistors, “extend(ing) elevationally” “elevationally-extending”, “extend(ing) horizontally”, “horizontally-extending” and the like, are with reference to orientation of the base length along which current flows in operation between the emitter and collector. In some embodiments, any component, feature, and/or region that extends elevationally extends vertically or within 10° of vertical.

Further, “directly above”, “directly below”, and “directly under” require at least some lateral overlap (i.e., horizontally) of two stated regions/materials/components relative one another. Also, use of “above” not preceded by “directly” only requires that some portion of the stated region/material/component that is above the other be elevationally outward of the other (i.e., independent of whether there is any lateral overlap of the two stated regions/materials/components). Analogously, use of “below” and “under” not preceded by “directly” only requires that some portion of the stated region/material/component that is below/under the other be elevationally inward of the other (i.e., independent of whether there is any lateral overlap of the two stated regions/materials/components).

Any of the materials, regions, and structures described herein may be homogenous or non-homogenous, and regardless may be continuous or discontinuous over any material which such overlie. Where one or more example composition(s) is/are provided for any material, that material may comprise, consist essentially of, or consist of such one or more composition(s). Further, unless otherwise stated, each material may be formed using any suitable existing or future-developed technique, with atomic layer deposition, chemical vapor deposition, physical vapor deposition, epitaxial growth, diffusion doping, and ion implanting being examples.

Additionally, “thickness” by itself (no preceding directional adjective) is defined as the mean straight-line distance through a given material or region perpendicularly from a closest surface of an immediately-adjacent material of different composition or of an immediately-adjacent region. Additionally, the various materials or regions described herein may be of substantially constant thickness or of variable thicknesses. If of variable thickness, thickness refers to average thickness unless otherwise indicated, and such material or region will have some minimum thickness and some maximum thickness due to the thickness being variable. As used herein, “different composition” only requires those portions of two stated materials or regions that may be directly against one another to be chemically and/or physically different, for example if such materials or regions are not homogenous. If the two stated materials or regions are not directly against one another, “different composition” only requires that those portions of the two stated materials or regions that are closest to one another be chemically and/or physically different if such materials or regions are not homogenous. In this document, a material, region, or structure is “directly against” another when there is at least some physical touching contact of the stated materials, regions, or structures relative one another. In contrast, “over”, “on”, “adjacent”, “along”, and “against” not preceded by “directly” encompass “directly against” as well as construction where intervening material(s), region(s), or structure(s) result(s) in no physical touching contact of the stated materials, regions, or structures relative one another.

Herein, regions-materials-components are “electrically coupled” relative one another if in normal operation electric current is capable of continuously flowing from one to the other and does so predominately by movement of subatomic positive and/or negative charges when such are sufficiently generated. Another electronic component may be between and electrically coupled to the regions-materials-components. In contrast, when regions-materials-components are referred to as being “directly electrically coupled”, no intervening electronic component (e.g., no diode, transistor, resistor, transducer, switch, fuse, etc.) is between the directly electrically coupled regions-materials-components.

Any use of “row” and “column” in this document is for convenience in distinguishing one series or orientation of features from another series or orientation of features and along which components have been or may be formed. “Row” and “column” are used synonymously with respect to any series of regions, components, and/or features independent of function. Regardless, the rows may be straight and/or curved and/or parallel and/or not parallel relative one another, as may be the columns. Further, the rows and columns may intersect relative one another at 90° or at one or more other angles (i.e., other than the straight angle).

The composition of any of the conductive/conductor/conducting materials herein may be conductive metal material and/or conductively-doped semiconductive/semiconductor/semiconducting material. “Metal material” is any one or combination of an elemental metal, any mixture or alloy of two or more elemental metals, and any one or more metallic compound(s).

Herein, any use of “selective” as to etch, etching, removing, removal, depositing, forming, and/or formation is such an act of one stated material relative to another stated material(s) so acted upon at a rate of at least 2:1 by volume. Further, any use of selectively depositing, selectively growing, or selectively forming is depositing, growing, or forming one material relative to another stated material or materials at a rate of at least 2:1 by volume for at least the first 75 Angstroms of depositing, growing, or forming.

Unless otherwise indicated, use of “or” herein encompasses either and both.

### Conclusion

In some embodiments, a method used in forming memory circuitry comprises forming parallel and spaced lower walls in semiconductor material. Individual of the lower walls comprise wall material and have a top that is spaced below a top of the semiconductor material. Semiconductive material is epitaxially formed from the semiconductor material to cover over the individual lower walls. A void space is between the top of the individual lower walls and the epitaxially-formed semiconductive material. Vertically-alternating layers comprising silicon material and silicon-germanium material are epitaxially formed directly above the semiconductor material and the semiconductive-material-covered lower walls. Parallel and spaced trenches are etched through the vertically-alternating layers. The trenches individually are directly above and longitudinally along one of the individual lower walls. The trenches are etched through individual of the void spaces to the individual lower walls and use the wall material of the individual lower walls as an etch stop during such etching. After the etching, the silicon-germanium material is removed selectively relative to the silicon material and forms vertically-alternating tiers of insulative material and memory cells. The memory cells individually comprise a capacitor and comprise a horizontally-oriented transistor having a channel comprising the epitaxially-formed silicon material.

In some embodiments, a method used in forming memory circuitry comprises forming parallel and spaced lower walls in semiconductor material. Individual of the lower walls comprise insulating material and have a top that is spaced below a top of the semiconductor material. Semiconductive material is epitaxially formed from the semiconductor material to cover the top of the individual lower walls. Vertically-alternating layers comprising silicon material and silicon-germanium material are epitaxially formed directly above the semiconductor material and the semiconductive-material-covered lower walls. Parallel and spaced trenches are etched through the vertically-alternating layers. The trenches individually are directly above and longitudinally along one of the individual lower walls. The trenches are etched to the individual lower walls and use the insulating material of the individual lower walls as an etch stop during the etching of the trenches. After the etching, the silicon-germanium material is removed selectively relative to the silicon material and forms vertically-alternating tiers of insulative material and memory cells. The memory cells individually comprise a capacitor and comprise a horizontally-oriented transistor having a channel comprising the epitaxially-formed silicon material. Insulator material is formed in remaining of the trenches directly above and directly against the insulating material of the lower walls.

In some embodiments, a method used in forming memory circuitry comprises forming parallel and spaced first trenches in semiconductor material. Semiconductive material is epitaxially formed from the semiconductor material to cover over individual of the first trenches to leave at least a portion of the individual first trenches directly under the epitaxially-formed semiconductor material. Vertically-alternating layers comprising silicon material and silicon-germanium material are epitaxially formed directly above the semiconductor material and the semiconductive-material-covered first trenches. Parallel and spaced second trenches are etched through the vertically-alternating layers. The second trenches individually are directly above and longitudinally along one of the individual covered first trenches. The second trenches are etched to the first trenches to interconnect the first and second trenches together. After the etching, the silicon-germanium material is removed selectively relative to the silicon material and forms vertically-alternating tiers of insulative material and memory cells. The memory cells individually comprise a capacitor and comprise a horizontally-oriented transistor having a channel comprising the epitaxially-formed silicon material.

In some embodiments, memory circuitry comprises vertically-alternating tiers of insulative material and memory cells. The memory cells individually comprise a capacitor and a horizontally-oriented transistor. Semiconductor material is directly below the vertically-alternating tiers. Insulative vertical walls extend through the vertically-alternating tiers into the semiconductor material there-below. Individual of the insulative vertical walls are below a top of the semiconductor material comprising an upper portion directly above and joined with a lower portion. The individual insulative vertical walls comprise at least one external jog surface in a vertical cross-section in and below the top of the semiconductor material where the upper and lower portions join. The lower portion is wider in the vertical cross-section in the semiconductor material than the upper portion where the upper and lower portions join in the semiconductor material.

In compliance with the statute, the subject matter disclosed herein has been described in language more or less specific as to structural and methodical features. It is to be understood, however, that the claims are not limited to the specific features shown and described, since the means herein disclosed comprise example embodiments. The claims are thus to be afforded full scope as literally worded, and to be appropriately interpreted in accordance with the doctrine of equivalents.

1. A method used in forming memory circuitry, comprising:
forming parallel and spaced lower walls in semiconductor material, individual of the lower walls comprising wall material and having a top that is spaced below a top of the semiconductor material;
epitaxially forming semiconductive material from the semiconductor material to cover over the individual lower walls, a void space being between the top of the individual lower walls and the epitaxially-formed semiconductive material;
epitaxially forming vertically-alternating layers comprising silicon material and silicon-germanium material directly above the semiconductor material and the semiconductive-material-covered lower walls;
etching parallel and spaced trenches through the vertically-alternating layers, the trenches individually being directly above and longitudinally along one of the individual lower walls, the trenches being etched through individual of the void spaces to the individual lower walls and using the wall material of the individual lower walls as an etch stop during such etching; and
after the etching, removing the silicon-germanium material selectively relative to the silicon material and forming vertically-alternating tiers of insulative material and memory cells, the memory cells individually comprising a capacitor and comprising a horizontally-oriented transistor having a channel comprising the epitaxially-formed silicon material.

2. The method of claim 1 wherein the wall material comprises insulating material, at least some of the insulating material of the lower walls remaining in a finished-circuitry construction.

3. The method of claim 1 wherein a bottom of individual of the trenches is narrower than the top of the individual lower wall to which such individual trench is etched.

4. A method used in forming memory circuitry, comprising:
forming parallel and spaced lower walls in semiconductor material, individual of the lower walls comprising insulating material and having a top that is spaced below a top of the semiconductor material;
epitaxially forming semiconductive material from the semiconductor material to cover the top of the individual lower walls;
epitaxially forming vertically-alternating layers comprising silicon material and silicon-germanium material directly above the semiconductor material and the semiconductive-material-covered lower walls;
etching parallel and spaced trenches through the vertically-alternating layers, the trenches individually being directly above and longitudinally along one of the individual lower walls, the trenches being etched to the individual lower walls and using the insulating material of the individual lower walls as an etch stop during the etching of the trenches;
after the etching, removing the silicon-germanium material selectively relative to the silicon material and forming vertically-alternating tiers of insulative material and memory cells, the memory cells individually comprising a capacitor and comprising a horizontally-oriented transistor having a channel comprising the epitaxially-formed silicon material; and
forming insulator material in remaining of the trenches directly above and directly against the insulating material of the lower walls.

5. The method of claim 4 wherein the insulating material of the lower walls and the insulator material collectively comprise insulative vertical walls extending through the vertically-alternating tiers into the semiconductor material, individual of the insulative vertical walls below a top of the semiconductor material comprising an upper portion directly above and joined with a lower portion, the individual insulative vertical walls comprising at least one external jog surface in a vertical cross-section in and below the top of the semiconductor material where the upper and lower portions join, the lower portion being wider in the vertical cross-section in the semiconductor material than the upper portion where the upper and lower portions join in the semiconductor material.

6. The method of claim 5 wherein the external jog surface includes a part that is horizontal in the vertical cross-section.

7. The method of claim 5 comprising two external jog surfaces in the individual insulative vertical walls in the vertical cross-section.

8. The method of claim 7 wherein the two external jog surfaces individually include a part that is horizontal in the vertical cross-section.

9. The method of claim 4 wherein the channel is horizontally between two source/drain regions, the capacitor being directly electrically coupled to one of the source/drain regions in individual of the memory-cell tiers; and further comprising:
forming a vertical digit line extending through the vertically-alternating tiers on each of two opposing lateral sides of individual of the remaining trenches in a vertical cross-section before forming the insulator material in the remaining trenches, the vertical digit line being directly electrically coupled to multiple of the other of the source/drain regions in different ones of the individual memory-cell tiers; and
forming the insulator material in the remaining trenches laterally between the two vertical digit lines therein.

10. The method of claim 9 wherein the insulating material of the lower walls and the insulator material collectively comprise insulative vertical walls extending through the vertically-alternating tiers into the semiconductor material, individual of the insulative vertical walls below a top of the semiconductor material comprising an upper portion directly above and joined with a lower portion, the individual insulative vertical walls comprising at least one external jog surface in a vertical cross-section in and below the top of the semiconductor material where the upper and lower portions join, the lower portion being wider in the vertical cross-section in the semiconductor material than the upper portion where the upper and lower portions join in the semiconductor material.

11. The method of claim 10 wherein the external jog surface includes a part that is horizontal in the vertical cross-section.

12. The method of claim 10 comprising two external jog surfaces in the individual insulative vertical walls in the vertical cross-section.

13. The method of claim 12 wherein the two external jog surfaces individually include a part that is horizontal in the vertical cross-section.

14. A method used in forming memory circuitry, comprising:
forming parallel and spaced first trenches in semiconductor material;
epitaxially forming semiconductive material from the semiconductor material to cover over individual of the first trenches to leave at least a portion of the individual first trenches directly under the epitaxially-formed semiconductor material;
epitaxially forming vertically-alternating layers comprising silicon material and silicon-germanium material directly above the semiconductor material and the semiconductive-material-covered first trenches;
etching parallel and spaced second trenches through the vertically-alternating layers, the second trenches individually being directly above and longitudinally along one of the individual covered first trenches, the second trenches being etched to the first trenches to interconnect the first and second trenches together; and
after the etching, removing the silicon-germanium material selectively relative to the silicon material and forming vertically-alternating tiers of insulative material and memory cells, the memory cells individually comprising a capacitor and comprising a horizontally-oriented transistor having a channel comprising the epitaxially-formed silicon material.

15. Memory circuitry comprising:
vertically-alternating tiers of insulative material and memory cells, the memory cells individually comprising a capacitor and a horizontally-oriented transistor;
semiconductor material directly below the vertically-alternating tiers; and
insulative vertical walls extending through the vertically-alternating tiers into the semiconductor material there-below, individual of the insulative vertical walls below a top of the semiconductor material comprising an upper portion directly above and joined with a lower portion, the individual insulative vertical walls comprising at least one external jog surface in a vertical cross-section in and below the top of the semiconductor material where the upper and lower portions join, the lower portion being wider in the vertical cross-section in the semiconductor material than the upper portion where the upper and lower portions join in the semiconductor material.

16. The memory circuitry of claim 15 wherein the external jog surface includes a part that is horizontal in the vertical cross-section.

17. The memory circuitry of claim 15 comprising two external jog surfaces in the individual insulative vertical walls in the vertical cross-section.

18. The memory circuitry of claim 17 wherein the two external jog surfaces individually include a part that is horizontal in the vertical cross-section.

19. The memory circuitry of claim 15 wherein the horizontally-oriented transistor comprises a field effect transistor have a channel region horizontally between two source/drain regions, the capacitor being directly electrically coupled to one of the source/drain regions in individual of the memory-cell tiers; and further comprising:
a vertical digit line extending through the vertically-alternating tiers on each of two opposing lateral sides of the individual insulative vertical walls in the vertical cross-section, the vertical digit line being directly electrically coupled to multiple of the other of the source/drain regions in different ones of the individual memory-cell tiers.

20. The memory circuitry of claim 19 wherein individual of the digit lines have a bottom that is not directly above the at least one jog surface in the vertical cross-section.

21. The memory circuitry of claim 20 comprising two external jog surfaces in the individual insulative vertical walls in the vertical cross-section.

22. The memory circuitry of claim 21 wherein the two external jog surfaces individually include a part that is horizontal in the vertical cross-section.

23. The memory circuitry of claim 19 wherein the external jog surface is directly under the other source/drain region of one of the memory cells in a lowest of the memory-cell tiers in the vertical cross-section.

24. The memory circuitry of claim 23 wherein individual of the digit lines have a bottom that is not directly above any of the jog surfaces in the vertical cross-section.

25. The memory circuitry of claim 23 comprising two external jog surfaces in the individual insulative vertical walls in the vertical cross-section, each of the jog surfaces being directly under the other source/drain region of one of the memory cells in a lowest of the memory-cell tiers in the vertical cross-section.

26. The memory circuitry of claim 25 wherein the two external jog surfaces individually include a part that is horizontal in the vertical cross-section.
